(19) United States
(12) Patent Application Publication
(10) Pub. No.: US 2024/0278379 A1
(43) Pub. Date: Aug. 22, 2024

(54) DOUBLE-SIDE POLISHING METHOD FOR WORK AND DOUBLE-SIDE POLISHING APPARATUS FOR WORK

(71) Applicant: SUMCO Corporation, Tokyo (JP)

(72) Inventors: Ryo KURAMOTO, Tokyo (JP); Taiki GOTO, Tokyo (JP)

(73) Assignee: SUMCO Corporation, Tokyo (JP)

(21) Appl. No.: 18/568,469

(22) PCT Filed: May 12, 2022
(86) PCT No.: PCT/JP2022/020108

§ 371 Date: Dec. 8, 2023

(30) Foreign Application Priority Data
Jun. 11, 2021 (JP) 2021-098146

(51) Int. Cl. B24B 37/005; B24B 37/08; B24B 49/10

(52) U.S. Cl. CPC B24B 37/005; B24B 37/08; B24B 49/10

(57) ABSTRACT

Based on the relational data that indicates the relationship between inter-plate distance, which is a distance between the upper plate and the lower plate at two or more positions where distances from the center of the rotating plate are different, and the flatness of the work, the optimal value of the inter-plate distance is calculated.

### TECHNICAL FIELD

This disclosure relates to a double-side polishing method for a work and a double-side polishing apparatus for a work.

### BACKGROUND

In the manufacture of semiconductor wafers such as silicon wafers, which are typical examples of works subjected to polishing, a double-side polishing process in which the front and back sides of the wafer are simultaneously polished is generally employed to obtain more precise quality with respect to the flatness and surface roughness of the wafers (e.g., PTL1).

### CITATION LIST

### Patent Literature

PTL 1: WO2014-002467 A1

### SUMMARY

### Technical Problem

In the double-side polishing, it is desirable to obtain a desired flatness of a work with high accuracy.

Therefore, the purpose of the present disclosure is to provide a double-side polishing method for a work and a double-side polishing apparatus for a work, that can obtain the desired flatness of the work with high accuracy.

### Solution to Problem

The gist structure of the present disclosure is as follows.

(1) A double-side polishing method for a work including holding a work on a carrier plate having one or more holding holes to hold a work, sandwiching the work with a rotating plate comprising a upper plate and a lower plate, and simultaneously polishing both sides of the work by rotating the rotating plate and the carrier plate relative to each other through the rotation of a sun gear provided at the center of the rotating plate and the rotation of an internal gear provided at the periphery of the rotating plate,
wherein the method includes:
a relational data obtaining process; obtaining relational data, in advance, that indicates the relationship between inter-plate distance, which is a distance between the upper plate and the lower plate at two or more positions where distances from the center of the rotating plate are different, and the flatness of the work,
an optimum distance calculation process; calculating, by a calculation section, the optimum value of the inter-plate distance at two or more positions where distances from the center of the rotating plate are different to obtain the desired flatness of the work, based on the relational data obtained in the relational data obtaining process,
a control process; controlling the shape of the rotating plate to control the inter-plate distance to the optimum value.

(2) The double-side polishing method for a work according to (1) above, wherein in the relational data obtaining process and the optimum distance calculation process, the two or more positions where distances from the center of the rotating plate are different include, at least, a radially outer end position of the rotating plate and a radially inner end position of the rotating plate.

(3) The double-side polishing method for a work according to (1) or (2) above, wherein
in the relational data obtaining process, differential relational data that indicates a relationship between; a difference between the inter-plate distances at only two positions where distances from the center of the rotating plate are different, and the flatness of the work is obtained in advance,
in the optimum distance calculation process, the optimum value of the difference is calculated, and
in the control process, the shape of the rotating plate is controlled to control the difference to the optimum value of the difference.

(4) The double-side polishing method for a work according to any one of (1) to (3) above, wherein the flatness of the work is the flatness indexed by GBIR.

(5) A double-side polishing apparatus for a work comprising a rotating plate having an upper plate and a lower plate, a sun gear provided at the center of the rotating plate, an internal gear provided at the periphery of the rotating plate, and a carrier plate provided between the upper plate and the lower plate having one or more holding holes to hold a work,
wherein the apparatus comprises:
a calculation section that calculates the optimum value of inter-plate distance, which is a distance between the upper plate and the lower plate at two or more positions where distances from the center of the rotating plate are different, to obtain the desired flatness of the work, based on previously obtained relational data indicating a relationship between the inter-plate distance at two or more positions where distances from the center of the rotating plate are different and the flatness of the work, and
a control section that controls the shape of the rotating plate to control the inter-plate distance to the optimum value.

(6) The double-side polishing apparatus for a work according to (5) above, wherein the two or more positions where distances from the center of the rotating plate are different include, at least, a radially inner end position of the rotating plate and a radially outer end position of the rotating plate.

(7) The double-side polishing apparatus for a work according to (5) or (6) above, wherein the flatness of the work is the flatness indexed by GBIR.

### Advantageous Effect

According to the present disclosure, it is possible to provide a double-side polishing method for a work and a double-side polishing apparatus for a work, that can obtain the desired flatness of the work with high accuracy.

### BRIEF DESCRIPTION OF THE DRAWINGS

In the accompanying drawings:

FIG. 1 is a cross-sectional schematic illustration of an example of the double-side polishing apparatus for a work that can be used for the double-side polishing method for a work according to one embodiment of this disclosure;

FIG. 2 is a plan view of the apparatus illustrated in FIG. 1 as viewed from the upper plate to the lower plate side;

FIG. 3 is a flowchart of the double-side polishing method of a work according to one embodiment of this disclosure;

FIG. 4 is a figure demonstrating the distance between the upper plate and the lower plate, and its measurement;

FIG. 5 illustrates the relationship between inter-plate distance (difference) and the flatness of the work (circumferential average value of GBIR);

FIG. 6 illustrates cooling water channels provided with the upper plate (the figure above) and schematically illustrates the change in shape of the upper plate due to the temperature of the cooling water (the figure below);

FIG. 7A illustrates an example of controlling the shape of the rotating plate by mechanical forces;

FIG. 7B illustrates another example of controlling the shape of the rotating plate by mechanical forces; and

FIG. 8 provides the results in Examples.

### DETAILED DESCRIPTION

The following is a detailed illustration of the embodiment(s) of the present disclosure with reference to the drawings.

### (Double-Side Polishing Method)

The following is a description of the double-side polishing method for a work according to one embodiment of this disclosure. First, an example of the double-side polishing apparatus for a work that can be used for the method of this disclosure will be outlined.

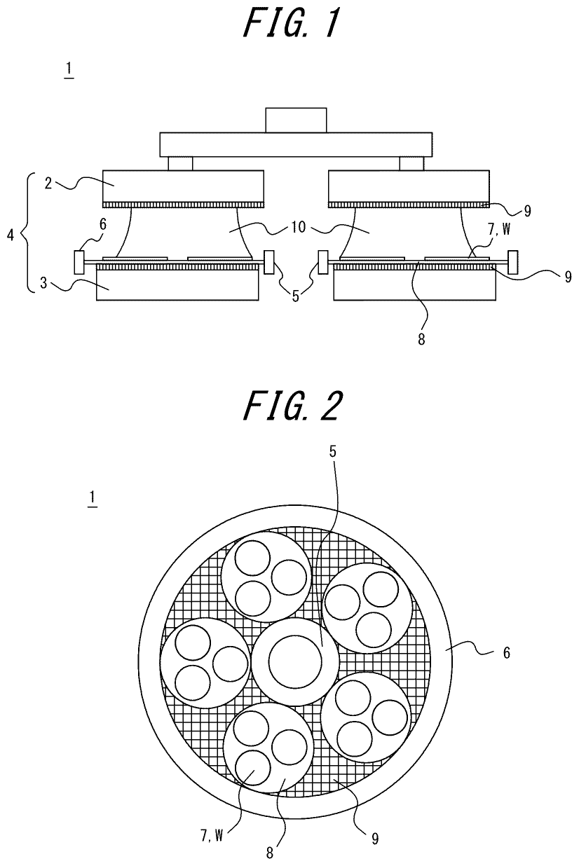

FIG. 1 is a cross-sectional schematic illustration of an example of the double-side polishing apparatus for a work that can be used for the double-side polishing method for a work according to one embodiment of this disclosure.

As illustrated in FIG. 1 and FIG. 2, this double-side polishing apparatus 1 comprises a rotating plate 4 having an upper plate 2 and a lower plate 3, a sun gear 5 provided at the center of the rotating plate 4, an internal gear 6 provided at the periphery of the rotating plate 4, a carrier plate 8 provided between the upper plate 2 and the lower plate 3 having one or more holding holes 7 (three in the illustrated example) to hold a work (a silicon wafer in this example) W. The lower surface of the upper plate 2 and the upper surface of the lower plate are each attached with a polishing pad 9.

Using this apparatus 1, the work W is held on the carrier plate 8 having one or more holding holes 7 to hold the work W, the work W is sandwiched with the rotating plate 4 comprising the upper plate 2 and the lower plate 3, and both sides of the work W can be simultaneously polished by rotating the rotating plate 4 and the carrier plate 8 relative to each other through the rotation of the sun gear 5 provided at the center of the rotating plate 4 and the rotation of the internal gear 6 provided at the periphery of the rotating plate 4, while supplying polishing slurry 10.

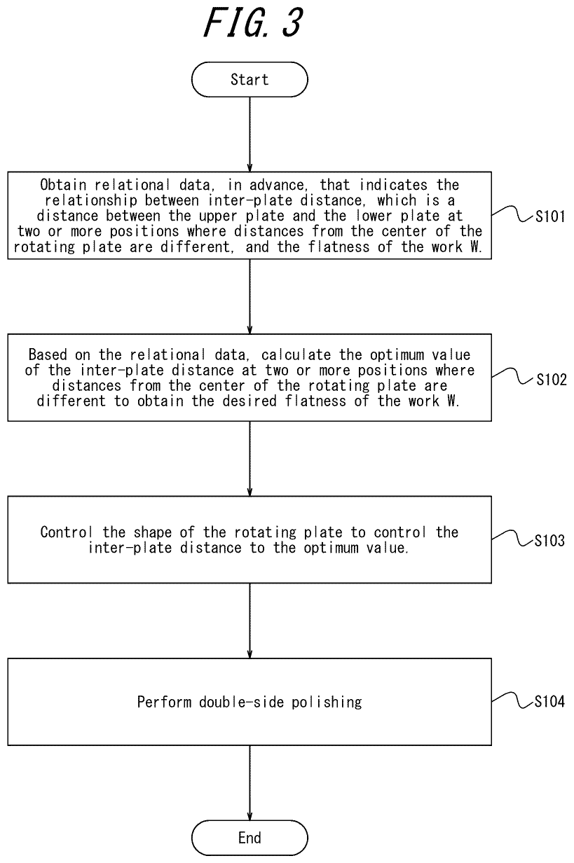

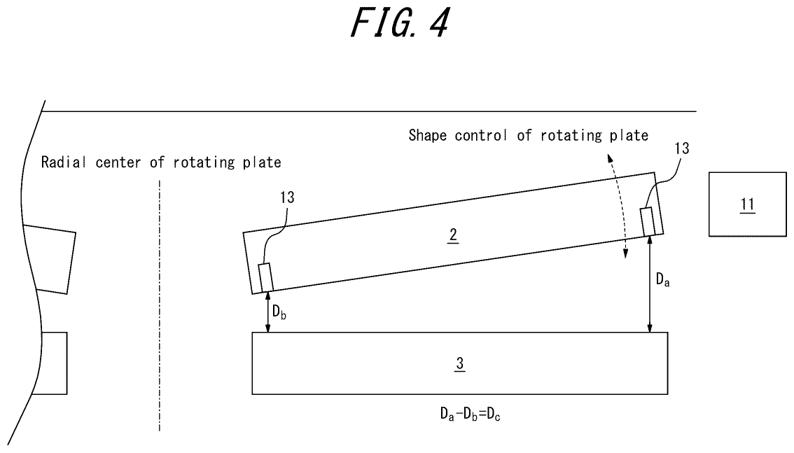

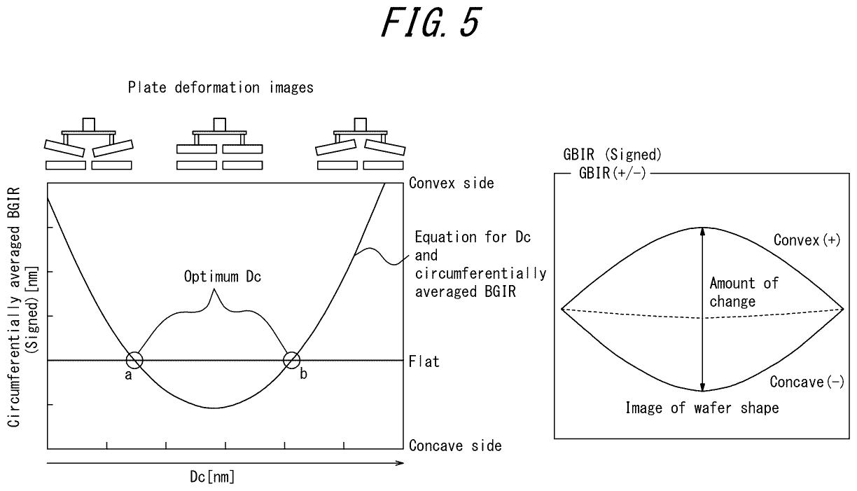

FIG. 3 is a flowchart of the double-side polishing method of a work according to one embodiment of this disclosure. FIG. 4 is a figure demonstrating the distance between the upper plate and the lower plate, and its measurement. FIG. 5 illustrates the relationship between the inter-plate distance (difference) and the flatness of the work (circumferential average of GBIR). The following is a description of each process of the method according to this embodiment.

As illustrated in FIG. 3, in the method according to this embodiment, the relational data that indicates the relationship between the inter-plate distance, which is a distance between the upper plate 2 and the lower plate 3 (distance parallel to the axis of the sun gear 5) at two or more positions where distances from the center of the rotating plate 4 are different, and the flatness of the work W is obtained in advance (Step S101: Relational data obtaining process). Such relational data can be obtained in advance, for example, by measuring and recording the above inter-plate distance at the relevant positions and measuring and recording the flatness of the work W after double-side polishing performed at that inter-plate distance, and it is preferred to obtain a sufficient number of data at various distances.

As illustrated in FIG. 4, in this example, the inter-plate distance shall be taken at only two positions where distances from the center of the rotating plate 4 are different. In this example, the two positions are the radially inner end position of the rotating plate 4 (the position up to 15% of the diameter from the radially inner end to the radially outer side) and the radially outer end position of the rotating plate 4 (the position up to 15% of the diameter from the radially outer end to the radially inner side). In this example, the two positions are at the same angle from the center of the rotating plate, therefore the two positions and the center of the rotating plate are on the same line in a plan view. However, in this disclosure, the two (or more) positions can be at different angles from the center of the rotating plate and at different distances from the center of the rotating plate. In this example, differential relational data that indicates the relationship between: the difference Dc (mm), which is the difference between the inter-plate distance Da (mm) at the radially outer end position of the rotating plate 4 and the inter-plate distance db (mm) at the radially inner end position of the rotating plate 4, and the flatness of the work W is obtained in advance. In this example, the flatness of the work W is the flatness indexed by GBIR (GlobalBackside Ideal focalplane Range) and shall be averaged over the entire circumference of the work W. For example, when the work W is a wafer, the radial center of the wafer is set to 0 mm, and the average thickness on the circumference can be calculated for each radial distance at 1 mm radial intervals (however, in this example, a region up to 2 mm radially inward from the radially outer end of the wafer is excluded). For example, when the diameter of the wafer is 300 mm, the maximum−minimum value can be calculated among the average thickness data of 148 (=150−2) obtained and the thickness at the center of the wafer, and that difference can be used as the circumferential average value of GBIR.

As illustrated in FIG. 5 (image on the left), the relationship between the above difference Dc and the circumferential average value of GBIR is, in this case, like a graph approximated by a quadratic equation. This is considered to be due to the following reasons. If the upper and lower plates are parallel, the wafer shape could be considered to be flat, however in reality, the center of the wafer has a higher temperature and thus a higher polishing speed, resulting in a concave shape with a depressed center. On the other hand, as in the state of the left image among three of the upper plate deformation images illustrated above the graph in FIG. 5 (image on the left), as the inter-plate distance at the radially inner end becomes smaller than the inter-plate distance at the radially outer end, the upper plate comes into contact with the wafer in a tilted state, and the addition of the wafer's rotation to it strengthens the effect of forming a convex shape with a raised center. This is almost the same when the inter-plate distance at the radially inner end is larger than the inter-plate distance at the radially outer end, as in the state of the right image of the plate deformation images in FIG. 5 (image on the left). Therefore, the relationship between the aforementioned difference Dc and the circumferential average value of GBIR is almost symmetrical. The reason why this relationship is represented by a quadratic curve is presumably because the final shape is determined by a combination of several actions: physical action (plate) for convexification and chemical action (heat) for concavification. As illustrated in FIG. 5 (image on the right), as an example, when the work W is a wafer, the circumferential average value of GBIR is positive for a convex shape with a thicker center.

In obtaining the relational data in step S101, such approximate formulas and other formulas (not limited to quadratic equations) can be obtained in advance. Note, that this example illustrates an example of calculating the difference between two positions for the aforementioned inter-plate distance and obtaining differential relational data between that difference and the flatness of the work in advance. In this case, since the two variables in the formula are Dc and the circumferential average value of GBIR, the advantage is that the formula is easy to obtain by approximation or other means. On the other hand, it is not necessary to calculate the difference, and a formula with three variables, for example, Da, db, and the circumferential average value of GBIR, can be obtained when calculating the inter-plate distance at only two positions. Similarly, when calculating the inter-plate distance at n positions, for example, a formula with n+1 variables can be obtained, or the number of variables can be reduced by taking differences or other operations.

In addition, in the step S101, in case that many other data were obtained, the relationship between the inter-plate distance and the flatness of the work can also be obtained as a mapping (a group of data that corresponds the inter-plate distance and the flatness of the work). In this case, in the above example, the difference Dc that is closest to the circumferential average value of the desired GBIR can be searched and determined on the mapping.

As another method, the optimum inter-plate distance can be output; by performing learning with a large number of sufficient data as training data through machine learning methods, creating an artificial intelligence model (such as a neural network) with the flatness of the work as the explanatory variable (input) and the inter-plate distance at two or more positions where distances from the center of the rotating plate 4 are different as the objective variable (output), and inputting the desired flatness of the work into this artificial intelligence model. It is also possible to create an artificial intelligence model with the inter-plate distance as the input and the flatness of the work as the output so that the optimum inter-plate distance can be calculated by any known method of inverse analysis.

Regarding the above relational data, the double-side polishing apparatus can be configured to comprise a memory section (any known memory) and store the data in the memory section, and/or to comprise a communication section and send and receive the relational data.

Referring to FIG. 3, in the method of the present embodiment, then, the calculation section 11 calculates the optimum value of the inter-plate distance at two or more positions where distances from the center of the rotating plate 4 are different to obtain the desired flatness of the work W, based on the relational data obtained in the relational data obtaining process (Step S101) (Step S102: Optimum distance calculation process). The calculation section 11 (see FIG. 4, omitted in FIG. 1) can be any known computer or other device. For example, if a formula providing the relationship between the inter-plate distance and the flatness of the work is obtained in step S101, the desired flatness value of the work can be substituted into the formula to calculate the optimum value of the inter-plate distance. For example, if the above relationship is obtained as a mapping, the value closest to the desired flatness value of the work can be used as the optimum value. Also, for example, if an artificial intelligence model providing the relationship between the inter-plate distance and the flatness of the work is obtained, the optimum value of the inter-plate distance can be calculated by forward or inverse analysis.

In this example, the optimum value of the above differential Dc to obtain the desired flatness of the work is calculated based on the aforementioned differential relational data for only two positions, the radially inner end position and the radially outer end position of the rotating plate 4.

FIG. 5 (image on the left) illustrates the case where the wafer is flat (the circumferential average of GBIR is 0) as the circumferential average of GBIR for the desired wafer. In this case, the quadratic equation intersects with the line at two points, so two optimum values of Dc are calculated (point a and point b in the image). If multiple optimum values of Dc are calculated, any of the optimum values may be adopted. As an example, but is not limited to, the one that makes it easier to control the plate shape (i.e., the one that requires less variation in the inter-plate distance) can be adopted. When controlling the inter-plate distance to the optimum value of Dc, either or both Da and db can be controlled. Note, that the desired shape of the wafer is not limited to being flat, and the optimum Dc can be calculated in the same way when the wafer has either a convex or concave shape (i.e., the circumferential average value of GBIR is positive or negative).

Following the above, in the method of the present embodiment, the control section 12 controls the shape of the rotating plate 4 to control the inter-plate distance to the above optimum value (Step S103: Control process). In this example, the difference Dc is controlled to the above optimum value of the difference. In this control process, the shape of the rotating plate 4 is preferably controlled by mechanical forces or thermal deformation.

In controlling the inter-plate distance, it is preferable to control it while measuring the distance between the upper plate 2 and the lower plate 3 at two or more positions where distances from the center of the rotating plate are different, using the measuring section 13 (see FIG. 4, omitted in FIG. 1). The measuring section 13 can be any known sensor or the like, for example, an eddy current sensor capable of measuring distance.

The control section 12 can be configured to receive instructions based on the calculation results from the calculation section 11.

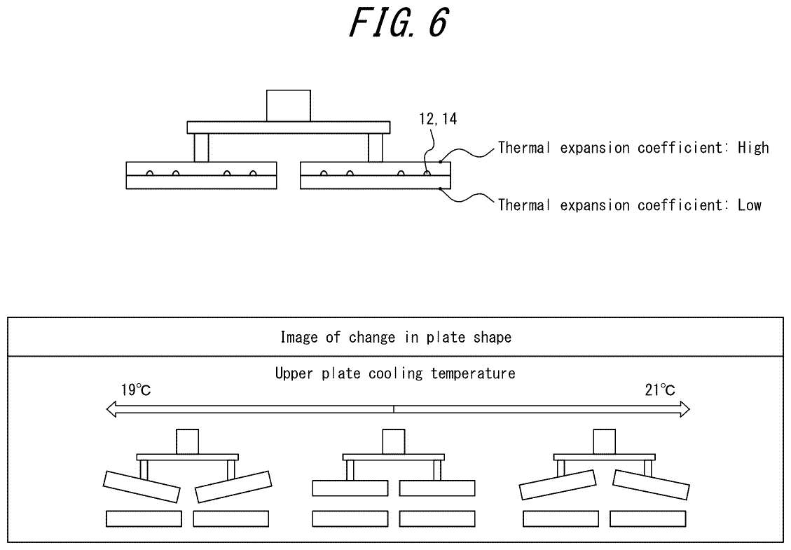

The following is an example and explanation of the control of the shape of the rotating plate by the control section 12. FIG. 6 illustrates cooling water channels provided with the upper plate (the image above) and schematically illustrates the change in shape of the upper plate due to the temperature of the cooling water (the image below). The example in FIG. 6 illustrates a rotating plate whose shape is controlled by thermal deformation.

In this example, the thermal expansion coefficient of the upper plate 2 is greater than that of the lower plate 3 (for example, different materials can be used to achieve such a relationship of the thermal expansion coefficient). The cooling water channels 14 are provided on the lower side of the upper plate 2 (at eight positions in this illustrated example). In this example, this cooling water channels 14 serves as the control section 12. The number and size of the cooling water channels 14 can be adjusted as needed to produce the desired change in shape.

As illustrated in FIG. 6 (the image below), when the cooling water flows into the cooling water channels 14 of the upper plate 2 and the temperature of the cooling water is low, due to the thermal expansion coefficient of the upper plate 2 is relatively large, radially outer side of the upper plate is lifted up due to thermal contraction of the upper plate and the inter-plate distance at radially inner side becomes smaller than that at the radially outer side. On the other hand, when the temperature of the cooling water is high, thermal expansion of the upper plate pushes down the radially outer side thereof and the inter-plate distance at the radially inner side becomes larger than that at the radially outer side. In this way, the shape of the upper plate 2 can be controlled by the temperature and flow rate of the cooling water, and the inter-plate distance can be controlled to the optimum value. During the control, for example, the inter-plate distance can be measured in real time by the measuring section 13, and the control can be stopped when it is measured that the desired inter-plate distance has been reached. When the desired inter-plate distance is reached, the cooling water continues to flow to maintain the shape. In this example, the inter-plate distance is controlled by controlling the shape of the upper plate 2, however the shape of the lower plate 3 may be controlled by the same method, or the shape of both the upper and lower plates may be configured to be controlled. Also, in the above example, the inter-plate distance at the radially inner side is illustrated to be larger or smaller than the inter-plate distance at the radially outer side, however there are various other methods of varying the inter-plate distance depending on the radial position. For example, by making the flow rate of cooling water near the radial center of the rotating plate larger than that at the radially outer end. For example, the inter-plate distance near the radial center of the rotating plate can be controlled to be larger or smaller than the inter-plate distance at the radially outer end of the rotating plate by increasing the flow rate of cooling water near the radial center of the rotating plate than that at the radially outer end.

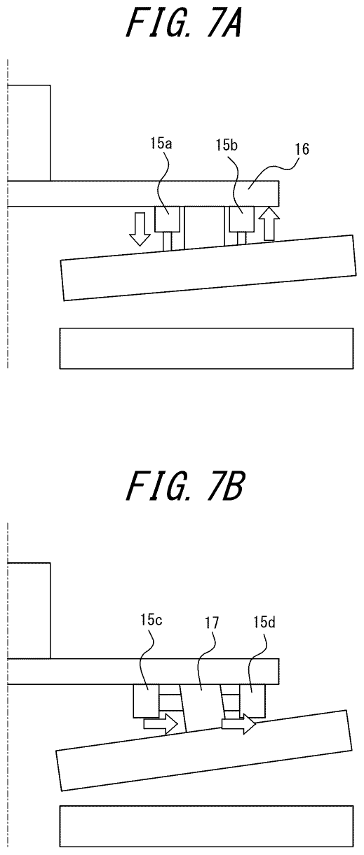

FIG. 7A illustrates an example of controlling the shape of the rotating plate by mechanical forces, and FIG. 7B illustrates another example of controlling the shape of the rotating plate by mechanical forces. These examples control the shape of the rotating plate by mechanical forces. In the example illustrated in FIG. 7A, two control members 15a and 15b are arranged one each with the fixing member 16, which fixes the upper plate 2, in between, and the control members 15a and 15b are configured to control the inter-plate distance by applying a direct force to the upper plate 2. In this example, the control members 15a and 15b have an extendable portion, for example as illustrated in the figure, which can be configured to apply a downward force at the radially inner side and deform upward at the radially outer side due to the expansion and contraction of this portion, so that the inter-plate distance at the radially inner side is smaller than the inter-plate distance at the radially outer side. In the example of FIG. 7B, two control members 15c and 15d are each fixed to the suspension member 17, which suspends the upper plate 2, with the suspension member 17 in between, and the control members 15c and 15d are configured to change the inclination of the upper plate 2 by applying force to the suspension member so that to control the inter-plate distance. In this example, the control member applies a force in the right direction as illustrated (from the radially inner side to the radially outer side), which causes the suspension member 17 to tilt, so that the upper plate 2 tilts up to the right in the figure and that the inter-plate distance at the radially inner side is smaller than the inter-plate distance at radially outer side. The shape of the lower plate 3 may be controlled by the same method, or the shape of both the upper and lower plates may be configured to be controlled. Also, in the above example, the inter-plate distance at the radially inner side is illustrated as if it were smaller than the inter-plate distance at the radially outer side, however it can be larger, or the inter-plate distance can be varied in various ways depending on the radial position, by varying the arrangement of the control members and the magnitude of the force applied by each control member.

In these examples, the control was performed by mechanical force or thermal deformation, however it is not limited to these, but can also use electromagnetic force, etc. Also, the above is only one example of mechanical and thermal deformation methods, and various methods can also be used.

After that, in this embodiment, double-side polishing is performed under the conditions of the optimized inter-plate distance (in this example, the optimum value of the difference Dc) (Step S104).

The following is a description of this double-side polishing method for a work.

According to this double-side polishing method for a work, double-side polishing can be performed upon obtaining in advance the above-mentioned relational data and controlling in advance the inter-plate distance to the optimum inter-plate distance to obtain the desired flatness of the work based on the relational data, therefore the desired flatness of the work can be obtained with high accuracy.

Here, as in this embodiment, in the relational data obtaining process and the optimum distance calculation process, it is preferable that the two or more positions where distances from the center of the rotating plate are different include, at least, a radially outer end position of the rotating plate and a radially inner end position of the rotating plate. This is because, as is clear from the explanation of the mechanism above, the difference in polishing action tends to be particularly pronounced between the radially inner end position and the radially outer end position, the inclusion of these positions allows for a better correlation between inter-plate distance and the flatness, which can further improve the accuracy of flatness control.

In addition, it is preferable that, in the relational data obtaining process, differential relational data indicating the relationship between; the difference between the distances between the upper plate and the lower plate at two positions where distances from the center of the rotating plate are different, and the flatness of the work is obtained in advance, in the optimum distance calculation process, the optimum value of the difference is calculated, and in the control process, the shape of the rotating plate is controlled to control the difference to the optimum value of the difference. By taking the difference, the process of the relational data can be simplified, and in controlling the shape of the rotating plate, the inter-plate distance can be controlled by simple shape control, for example, by changing the inclination of the upper plate or the lower plate.

Further, in the control process, it is preferable to control the shape of the rotating plate by mechanical force or thermal deformation. This is because it is relatively simple to control the rotating plate.

The flatness of the work is preferably the flatness indexed by GBIR. This is because the inter-plate distance and GBIR are strongly correlated, as described in the explanation of the mechanism above, and are suitable for obtaining the desired flatness of the work with high accuracy.

On the other hand, the index of flatness of the work is not limited to the above cases, and an index other than GBIR, which indicates the flatness of the entire surface of the work, can be used, or an index of flatness of a local area of the work (e.g., the outer periphery) can also be used. The following describes the case where ESFQD (Edge Site flatness Front reference least sQuare Deviation) specified in the SEMI standard M67 is used as an indicator.

The ESFQD value can be approximated by a linear equation with a negative slope with respect to Dc. The reasons for this are discussed below. The outer circumference shape has a significant effect on the sinking of the polishing pad due to the load from the rotating plate. A larger sinkage of the polishing pad results in a larger roll-off, while a smaller sinkage results in a smaller roll-off. When the inter-plate distance is smaller at the radially inner side than the radially outer side (state A), the load at radially inner side is larger and the amount of sinking of the polishing pad increases at the radially inner side. On the other hand, when the inter-plate distance is larger at the radially inner side than the radially outer side (state C), the load at radially outer side is larger and the amount of sinking of the polishing pad increases at the radially outer side. When the plate is flat (state B), the state is in between. Since the rotating plate is circular in a plan view, the circumferential speed at the radially inner side is lower than that of at the radially outer side, and the polishing speed is higher at the radially outer side. Therefore, since the amount of polishing at the radially outer side is larger than that of at the radially inner side, the roll-off tends to be largest in the state C, smallest in the state A, and intermediate between them in the state B.

Because of this relationship, an index of a local flatness (e.g., a flatness of outer periphery) of the work, such as EFSQD, may also be used as a measure of flatness of the work.

### (A Double-Side Polishing Apparatus)

The following is a description of a double-side polishing apparatus for a work according to one embodiment of this disclosure.

As already been described in the embodiment of the double-side polishing method for a work, the double-side polishing apparatus for a work according to this embodiment comprises a rotating plate 4 having an upper plate 2 and a lower plate 3, a sun gear 5 provided at the center of the rotating plate 4, an internal gear 6 provided at the periphery of the rotating plate 4, a carrier plate 8 provided between the upper plate 2 and the lower plate 3 having one or more holding holes 7 to hold a work W. The lower surface of the upper plate 2 and the upper surface of the lower plate are each attached with a polishing pad 9.

The double-side polishing apparatus for a work according to this embodiment further comprises a calculation section 11 that calculates the optimum value of inter-plate distance at two or more positions where distances from the center of the rotating plate 4 are different, to obtain the desired flatness of the work, based on previously obtained relational data indicating the relationship between the inter-plate distance at two or more positions where distances from the center of the rotating plate 4 are different and the flatness of the work.

In addition to that, the double-side polishing apparatus for a work according to this embodiment further comprises a control section 12 that controls the shape of the rotating plate 4 to control the inter-plate distance to the optimum value.

As illustrated in FIG. 4, the double-side polishing apparatus for a work according to this embodiment further comprises a measuring section 13, which measures the distance between the upper plate 2 and the lower plate 3 at two or more positions where distances from the center of the rotating plate 4 are different.

Details of the calculation section 11, the control section 12, and the measurement section 13 have already been described as devices that can be used for a double-side polishing apparatus, so repeated explanations will be omitted.

The double-side polishing apparatus for a work according to this embodiment can further comprise a memory section (memory), a communication section, a processor, etc., as appropriate, which are useful to obtain the above-mentioned effects.

According to the double-side polishing apparatus for a work according to this embodiment, double-side polishing can be performed upon controlling in advance the optimum inter-plate distance to obtain the desired flatness of the work based on the relational data, therefore the desired flatness of the work can be obtained with high accuracy.

It is preferable that the two or more positions where distances from the center of the rotating plate 4 are different include, at least, a radially inner end position of the rotating plate 4 and a radially outer end position of the rotating plate 4. This is because, as mentioned above, the accuracy of flatness control can be further enhanced.

In addition, it is preferable that the flatness of the work is the flatness indexed by GBIR. This is because, as mentioned above, it is suitable for obtaining the desired flatness of the work with high accuracy.

Also, it is preferable for the control section to control the shape of the rotating plate by mechanical force or thermal deformation. This is because it is relatively simple to control the rotating plate.

### (Example of Variations, Etc.)

In the above example, the two or more positions where distances from the center of the rotating plate 4 are different in the relational data obtaining process and the measurement process include at least the radially inner end position of the rotating plate 4 and the radially outer end position of the rotating plate 4. However, these positions do not have to be included as long as the two or more positions are at different distances from the center of the rotating plate 4.

Also, in the above example, the relational data was obtained and the optimum value was calculated for the above distances at only two positions where distances from the center of the rotating plate 4 are different. However, the obtaining of the relational data and the calculation of the optimum value can also be performed for the above distances at three or more positions where distances from the center of the rotating plate 4 are different.

In addition, in this double-side polishing method for a work, it is preferable to measure the flatness of the work after step S104 to determine whether the desired result has been obtained. The results can be used, for example, to update the relational data. For example, if there is a discrepancy between the target flatness of the work and the result thereof, the inter-plate distance to be adjusted can be corrected accordingly. Alternatively, if such a discrepancy occurs and more than one optimum value is calculated (two in the above quadratic example), the next time, the double-side polishing of the work can be done by using the other optimum value.

Examples of this disclosure are described below, however this disclosure is not limited in any way to the following examples.

### EXAMPLES

In order to verify the effectiveness of this disclosure, a test was conducted with (Example case) and without (Comparative Example case) the optimization of the inter-plate distance to measure the GBIR of works after double-side polishing and to calculate the average value in the circumferential direction.

Silicon wafers of p-type having diameter of 300 mm and the crystallographic orientation of <110> were used as works in Examples and Comparative Examples. The double-side polishing apparatus for a work illustrated in FIG. 1 was used. For the double-side polishing conditions, an alkali-based solution with colloidal silica was used as the polishing slurry, and the polishing rate was 0.3 μm/min.

In Examples, the relational data between the inter-plate distance at the radially inner end position (100 mm radially outward position from the radially inner end) and the radially outer end position (70 mm radially inward position from the radially outer end) of the rotating plate, and the flatness of the silicon wafer (circumferential average value of GBIR) were obtained in advance. For the circumferential average of GBIR, the average of the circumferential thickness can be calculated for each radial distance at 1 mm radial intervals, with the radial center of the wafer as 0 mm (however, in this example, the area up to 2 mm radially inward from the radially outer end of the wafer is excluded). For example, if the diameter of the wafer is 300 mm, the maximum−minimum value was calculated among the thickness average data of 148 (=150−2) obtained and the thickness at the center of the wafer, and the difference was used as the circumferential average value of GBIR.

The smaller value of the two intersections illustrated in FIG. 5 was then set as the optimum value of the difference Dc for the circumferential average value of the GBIR to be zero. After that, the inter-plate distance was controlled by the control section as illustrated in FIG. 6 to achieve the optimum value set for the difference Dc. After controlling the difference Dc to the optimum value, double-side polishing was performed, the GBIR after polishing was measured using KLA-TENCOR's WaferSight™, and its circumferential average value was calculated.

In Comparative Examples, double-sided polishing was performed without such optimization of the inter-plate distance, the GBIR after polishing was measured in the same way, and the circumferential average value was calculated.

Data for 105 wafers was collected for Examples, and data for 195 wafers was collected for Comparative Examples.

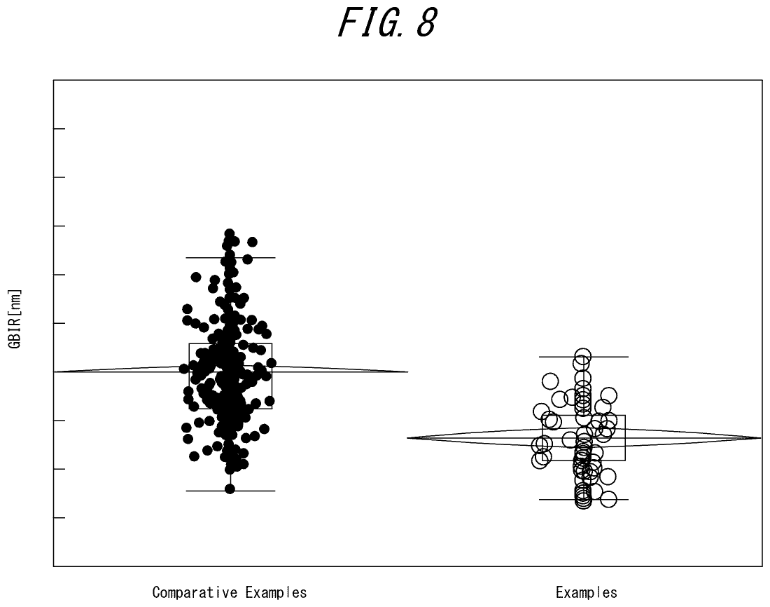

As provided in FIG. 8, in Examples with the optimization of the inter-plate distance: the GBIR value was smaller (closer to the target value of 0) than Comparative Examples without the optimization, and the variation of the GBIR value was also smaller when compared in terms of standard deviation.

### REFERENCE SIGNS LIST

1: Double-side polishing apparatus
2: Upper plate
3: Lower plate
4: Rotating plate
5: Sun gear
6: Internal gear
7: Holding hole
8: Carrier plate
9: Polishing pad
10: Polishing slurry
11: Calculation section
12: Control section
13: Measuring section
14: Cooling water channel
15a-15d: Control members
16: Fixing member
17: Suspension member

1. A double-side polishing method for a work including holding a work on a carrier plate having one or more holding holes to hold a work, sandwiching the work with a rotating plate comprising a upper plate and a lower plate, and simultaneously polishing both sides of the work by rotating the rotating plate and the carrier plate relative to each other through the rotation of a sun gear provided at the center of the rotating plate and the rotation of an internal gear provided at the periphery of the rotating plate,
wherein the method includes:
a relational data obtaining process; obtaining relational data, in advance, that indicates the relationship between inter-plate distance, which is a distance between the upper plate and the lower plate at two or more positions where distances from the center of the rotating plate are different, and the flatness of the work,
an optimum distance calculation process; calculating, by a calculation section, the optimum value of the inter-plate distance at two or more positions where distances from the center of the rotating plate are different to obtain the desired flatness of the work, based on the relational data obtained in the relational data obtaining process,
a control process; controlling the shape of the rotating plate to control the inter-plate distance to the optimum value.

2. The double-side polishing method for a work according to claim 1, wherein in the relational data obtaining process and the optimum distance calculation process, the two or more positions where distances from the center of the rotating plate are different include, at least, a radially outer end position of the rotating plate and a radially inner end position of the rotating plate.

3. The double-side polishing method for a work according to claim 1, wherein
in the relational data obtaining process, differential relational data that indicates a relationship between; a difference between the inter-plate distances at only two positions where distances from the center of the rotating plate are different, and the flatness of the work is obtained in advance,
in the optimum distance calculation process, the optimum value of the difference is calculated, and
in the control process, the shape of the rotating plate is controlled to control the difference to the optimum value of the difference.

4. The double-side polishing method for a work according to claim 1, wherein the flatness of the work is the flatness indexed by GBIR.

5. A double-side polishing apparatus for a work comprising a rotating plate having an upper plate and a lower plate, a sun gear provided at the center of the rotating plate, an internal gear provided at the periphery of the rotating plate, and a carrier plate provided between the upper plate and the lower plate having one or more holding holes to hold a work,
wherein the apparatus comprises:
a calculation section that calculates the optimum value of inter-plate distance, which is a distance between the upper plate and the lower plate at two or more positions where distances from the center of the rotating plate are different, to obtain the desired flatness of the work, based on previously obtained relational data indicating a relationship between the inter-plate distance at two or more positions where distances from the center of the rotating plate are different and the flatness of the work, and
a control section that controls the shape of the rotating plate to control the inter-plate distance to the optimum value.

6. The double-side polishing apparatus for a work according to claim 5, wherein the two or more positions where distances from the center of the rotating plate are different include, at least, a radially inner end position of the rotating plate and a radially outer end position of the rotating plate.

7. The double-side polishing apparatus for a work according to claim 5, wherein the flatness of the work is the flatness indexed by GBIR.
